(19) United States
(12) Patent Application Publication
(10) Pub. No.: US 2026/0075910 A1
(43) Pub. Date: Mar. 12, 2026

(54) SEMICONDUCTOR DEVICE AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Atsushi KITO, Nonoichi Ishikawa (JP); Takuya YASUTAKE, Kanazawa Ishikawa (JP)

(21) Appl. No.: 18/950,755

(22) Filed: Nov. 18, 2024

(30) Foreign Application Priority Data
Sep. 9, 2024 (JP) 2024-155103

(51) Int. Cl. H01L 29/40; H01L 21/265; H01L 21/266; H01L 29/06; H01L 29/739; H01L 29/78

(52) U.S. Cl. CPC H10D 64/117; H10D 12/481; H10D 30/668; H10D 62/127; H10D 64/01; H10D 64/112; H10P 30/204; H10P 30/21; H10P 30/22

(57) ABSTRACT

The first semiconductor layer includes a first region positioned between field plate electrodes adjacent to each other in the first direction, a second region positioned between field plate electrodes adjacent to each other in the second direction, and a third region positioned between field plate electrodes adjacent to each other with an intersection part interposed, the intersection part being between the gate electrode extending in the first direction and the gate electrode extending in the second direction. A first-conductivity-type impurity concentration of the first region and a first-conductivity-type impurity concentration of the second region are greater than a first-conductivity-type impurity concentration of the third region.

### CROSS-REFERENCE TO RELATED APPLICATION

This application is based upon and claims the benefit of priority from Japanese Patent Application No. 2024-155103, filed on Sep. 9, 2024; the entire contents of which are incorporated herein by reference.

### FIELD

Embodiments described herein relate generally to a semiconductor device and a method for manufacturing a semiconductor device.

### BACKGROUND

A power semiconductor device is known in which multiple field plate electrodes have a dot configuration in a square lattice arrangement when viewed in plan.

### BRIEF DESCRIPTION OF THE DRAWINGS

FIG. 1 is a schematic plan view of a semiconductor device according to an embodiment;

FIG. 2 is an A-A cross-sectional view of FIG. 1;

FIG. 3 is a B-B cross-sectional view of FIG. 1;

FIG. 4 is a C-C cross-sectional view of FIG. 1;

FIG. 5A and FIG. 5B are schematic plan views showing a method for manufacturing the semiconductor device of the embodiment;

FIG. 6A and FIG. 6B are schematic cross-sectional views showing a method for manufacturing the semiconductor device of the embodiment;

FIG. 7A and FIG. 7B are schematic plan views showing a method for manufacturing the semiconductor device of the embodiment; and

FIG. 8A and FIG. 8B are schematic cross-sectional views showing a method for manufacturing the semiconductor device of the embodiment.

### DETAILED DESCRIPTION

According to one embodiment, a semiconductor device includes a first electrode; a second electrode; a semiconductor part located between the first electrode and the second electrode; a plurality of field plate electrodes arranged in a first direction and a second direction inside the semiconductor part, the second direction being orthogonal to the first direction; and a gate electrode positioned between the plurality of field plate electrodes, the gate electrode extending in the first and second directions, the semiconductor part including a first semiconductor layer located on the first electrode, the first semiconductor layer being of a first conductivity type, a second semiconductor layer located on the first semiconductor layer, the second semiconductor layer being of a second conductivity type, and a third semiconductor layer located on the second semiconductor layer, the third semiconductor layer contacting the second electrode, the third semiconductor layer being of the first conductivity type and having a higher first-conductivity-type impurity concentration than the first semiconductor layer, the first semiconductor layer including a first region positioned between field plate electrodes among the plurality of field plate electrodes adjacent to each other in the first direction, a second region positioned between field plate electrodes among the plurality of field plate electrodes adjacent to each other in the second direction, and a third region positioned between field plate electrodes among the plurality of field plate electrodes adjacent to each other with an intersection part interposed, the intersection part being between the gate electrode extending in the first direction and the gate electrode extending in the second direction, a first-conductivity-type impurity concentration of the first region and a first-conductivity-type impurity concentration of the second region being greater than a first-conductivity-type impurity concentration of the third region.

Exemplary embodiments will now be described with reference to the drawings. Similar components in the drawings are marked with like reference numerals.

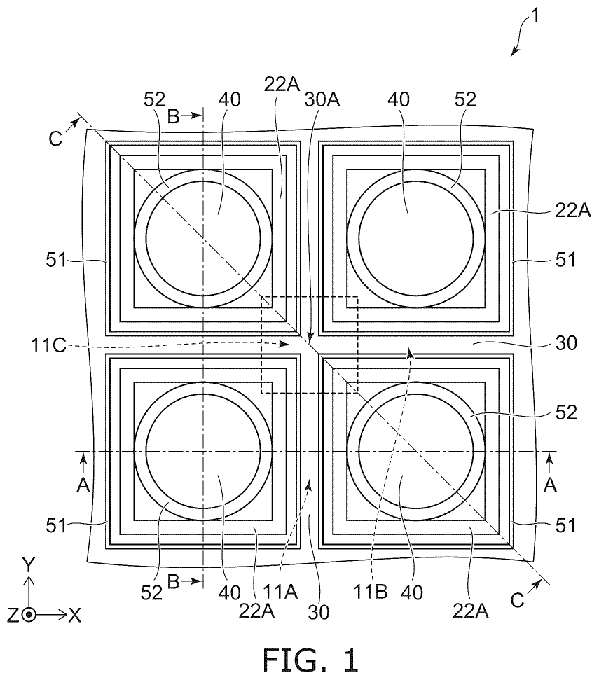

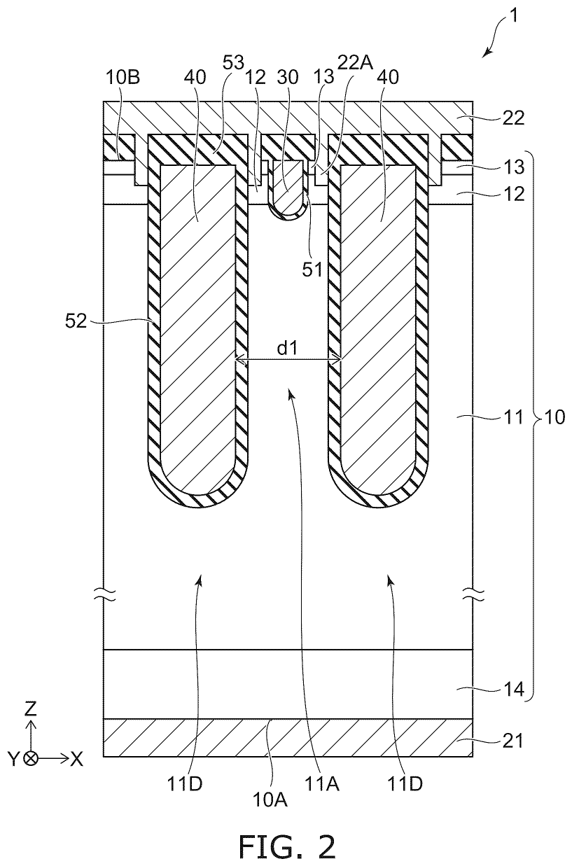

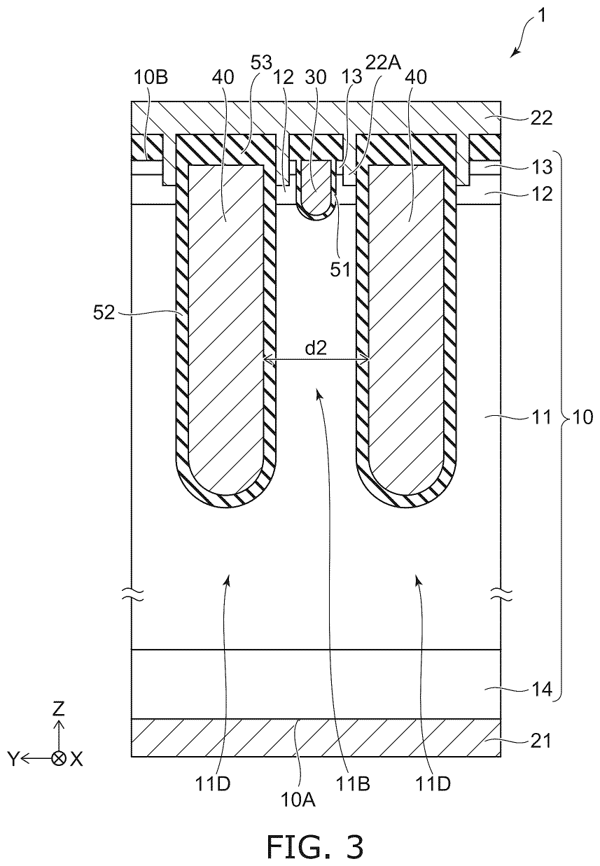

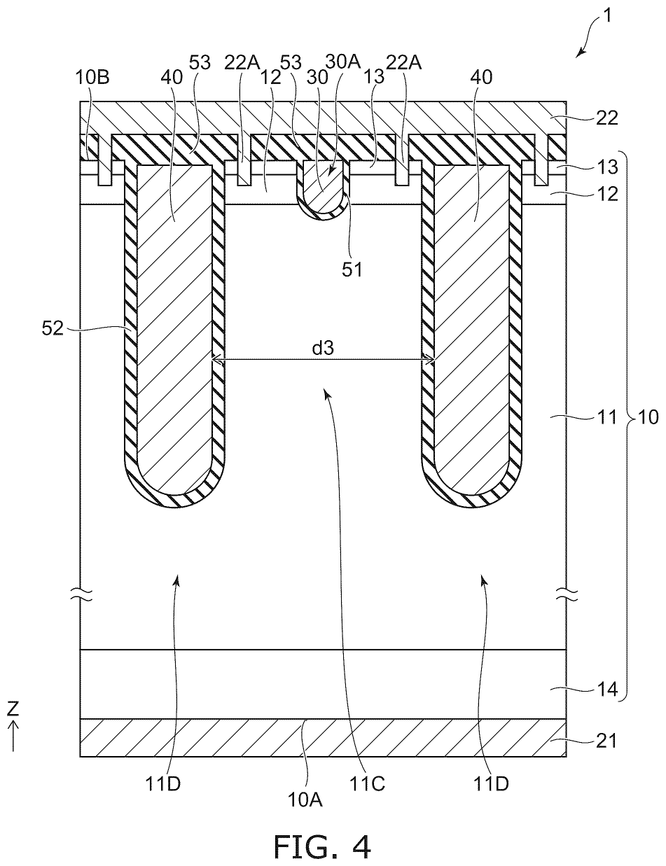

FIG. 1 is a schematic plan view showing an arrangement of major components of a semiconductor device 1 according to an embodiment. FIG. 2 is an A-A cross-sectional view of FIG. 1. FIG. 3 is a B-B cross-sectional view of FIG. 1. FIG. 4 is a C-C cross-sectional view of FIG. 1.

In the drawings, a direction along an X-axis is taken as a first direction X; a direction along a Y-axis is taken as a second direction Y; and a direction along a Z-axis is taken as a third direction Z. The first direction X, the second direction Y, and the third direction Z are orthogonal to each other. For example, the arrow direction of the Z-axis is taken as relatively upward.

As shown in FIGS. 2 to 4, the semiconductor device 1 according to the embodiment includes a first electrode 21, a second electrode 22, and a semiconductor part 10. The first electrode 21 and the second electrode 22 are positioned to be separated from each other in the third direction Z.

The semiconductor part 10 is positioned between the first electrode 21 and the second electrode 22 in the third direction Z. The semiconductor part 10 includes a first surface 10A and a second surface 10B. The first surface 10A faces the first electrode 21 in the third direction Z. The second surface 10B is positioned at the side opposite to the first surface 10A in the third direction Z.

For example, silicon can be used as the material of the semiconductor part 10. Or, for example, silicon carbide, gallium nitride, etc., may be used as the material of the semiconductor part 10. Although a first conductivity type is described as an n-type and a second conductivity type is described as a p-type in the semiconductor part 10 according to the embodiment, the first conductivity type may be the p-type; and the second conductivity type may be the n-type.

The semiconductor part 10 includes an n-type first semiconductor layer 11, a p-type second semiconductor layer 12 located on the first semiconductor layer 11, and an n-type third semiconductor layer 13 located on the second semiconductor layer 12. The n-type impurity concentration of the third semiconductor layer 13 is greater than the n-type impurity concentration of the first semiconductor layer 11. The semiconductor part 10 includes a fourth semiconductor layer 14 located between the first electrode 21 and the first semiconductor layer 11.

The semiconductor device 1 according to the embodiment has, for example, a vertical MOSFET (Metal-Oxide-Semiconductor Field-Effect Transistor) structure. In the MOSFET, the first electrode 21 functions as a drain electrode; the second electrode 22 functions as a source electrode; the first semiconductor layer 11 functions as a drift layer; the second semiconductor layer 12 functions as a base layer; the third semiconductor layer 13 functions as a source layer; and the fourth semiconductor layer 14 functions as an n-type drain layer that has a higher n-type impurity concentration than the first semiconductor layer 11.

Or, the semiconductor device according to the embodiment may have a vertical IGBT (Insulated Gate Bipolar Transistor) structure. In the IGBT, the first electrode 21 functions as a collector electrode; the second electrode 22 functions as an emitter electrode; the first semiconductor layer 11 functions as a drift layer; the second semiconductor layer 12 functions as a base layer; the third semiconductor layer 13 functions as an emitter layer; and the fourth semiconductor layer 14 functions as a p-type collector layer. In the IGBT, an n-type buffer layer that has a higher n-type impurity concentration than the first semiconductor layer 11 may be provided between the fourth semiconductor layer 14 (the collector layer) and the first semiconductor layer 11 (the drift layer).

The first electrode 21 contacts the first surface 10A of the semiconductor part 10. According to the embodiment, the first electrode 21 contacts the fourth semiconductor layer 14 and is electrically connected with the fourth semiconductor layer 14.

The second electrode 22 is located on the second surface 10B of the semiconductor part 10 with an insulating layer 53, which is described below, interposed. The second electrode 22 includes a contact part 22A that extends through the insulating layer 53 and reaches the second semiconductor layer 12. The third semiconductor layer 13 contacts the side surface of the contact part 22A and is electrically connected with the second electrode 22.

The semiconductor device 1 according to the embodiment further includes a gate electrode 30 and a gate insulating film 51. The gate electrode 30 extends downward from the second surface 10B of the semiconductor part 10 and is positioned inside the semiconductor part 10. The lower end of the gate electrode 30 is positioned inside the first semiconductor layer 11 lower than the p-n junction between the second semiconductor layer 12 and the first semiconductor layer 11. For example, conductive polycrystalline silicon can be used as the material of the gate electrode 30.

The gate insulating film 51 is located between the gate electrode 30 and the semiconductor part 10. The side surface of the gate electrode 30 faces the second semiconductor layer 12 via the gate insulating film 51.

The semiconductor device 1 according to the embodiment further includes a field plate electrode 40 and a field plate insulating film 52.

The field plate electrode 40 extends downward from the second surface 10B of the semiconductor part 10 and is positioned inside the semiconductor part 10. Multiple columnar field plate electrodes 40 inside the semiconductor part 10 are arranged in the first and second directions X and Y as shown in FIG. 1. The multiple field plate electrodes 40 have a square lattice arrangement in the first and second directions X and Y when viewed in plan. The shape of the field plate electrode 40 when viewed in plan is, for example, circular.

As shown in FIG. 2, the field plate electrode 40 does not reach the fourth semiconductor layer 14. The lower end portion of the field plate electrode 40 is positioned inside the first semiconductor layer 11. The shortest distance in the third direction Z between the first electrode 21 and the lower end portion of the field plate electrode 40 is less than the shortest distance in the third direction Z between the first electrode 21 and the lower end portion of the gate electrode 30. For example, conductive polycrystalline silicon can be used as the material of the field plate electrode 40.

The field plate insulating film 52 is located between the field plate electrode 40 and the semiconductor part 10 and between the field plate electrode 40 and the contact part 22A of the second electrode 22.

As shown in FIG. 1, the gate electrode 30 is positioned between the multiple field plate electrodes 40 and extends in the first and second directions X and Y when viewed in plan. FIG. 4 is a cross-sectional view of a portion including an intersection part 30A between the gate electrode 30 extending in the first direction X and the gate electrode 30 extending in the second direction Y, and is a C-C cross-sectional view along a direction oblique to the first and second directions X and Y. The contact part 22A of the second electrode 22 is positioned between the field plate electrode 40 and the gate electrode 30.

The semiconductor device 1 according to the embodiment further includes the insulating layer 53. The insulating layer 53 is located between the second electrode 22 and the second surface 10B of the semiconductor part 10, between the second electrode 22 and the upper surface of the gate electrode 30, and between the field plate electrode 40 and the second electrode 22.

As shown in FIGS. 1 and 2, the first semiconductor layer 11 includes a first region 11A positioned between the field plate electrodes 40 adjacent to each other in the first direction X.

As shown in FIGS. 1 and 3, the first semiconductor layer 11 includes a second region 11B positioned between the field plate electrodes 40 adjacent to each other in the second direction Y.

As shown in FIGS. 1 and 4, the first semiconductor layer 11 includes a third region 11C positioned between the field plate electrodes 40 adjacent to each other with the intersection part 30A of the gate electrode 30 interposed. In FIG. 1, the outer edge of the third region 11C when viewed in plan is virtually illustrated by a broken line.

As shown in FIG. 2, the shortest distance between the field plate electrodes 40 adjacent to each other in the first direction X is taken as a first distance d1. As shown in FIG. 3, the shortest distance between the field plate electrodes 40 adjacent to each other in the second direction Y is taken as a second distance d2. As shown in FIG. 4, the shortest distance between the field plate electrodes 40 adjacent to each other with the intersection part 30A of the gate electrode 30 interposed is taken as a third distance d3. The third distance d3 is greater than the first distance d1 and greater than the second distance d2. The first distance d1 and the second distance d2 are substantially the same.

The n-type impurity concentration of the first region 11A and the n-type impurity concentration of the second region 11B are greater than the n-type impurity concentration of the third region 11C. The n-type impurity concentration of the first region 11A and the n-type impurity concentration of the second region 11B are, for example, not less than 1.2 times and not more than 1.4 times the n-type impurity concentration of the third region 11C.

An n-type channel is formed in the region of the second semiconductor layer 12 facing the side surface of the gate electrode 30 when a first potential (e.g., a positive potential) is applied to the first electrode 21, a second potential (e.g., a ground potential) that is less than the first potential is applied to the second electrode 22, and a gate voltage that is not less than a threshold is applied to the gate electrode 30. A current flows between the first electrode 21 and the second electrode 22 via the fourth semiconductor layer 14, the first semiconductor layer 11, the channel, and the third semiconductor layer 13; and the semiconductor device 1 is set to the on-state.

In the off-state of the semiconductor device 1 in which the application of the voltage not less than the threshold to the gate electrode 30 is stopped, a depletion layer spreads from the p-n junction between the second semiconductor layer 12 and the first semiconductor layer 11 and from the boundary between the field plate insulating film 52 and the first semiconductor layer 11; and the breakdown voltage of the semiconductor device 1 is maintained.

For example, the field plate electrode 40 is electrically connected with the second electrode 22. Or, the field plate electrode 40 may be electrically connected with the gate electrode 30. In the off-state, such a field plate electrode 40 relaxes the electric field distribution of the first semiconductor layer 11 (the drift layer) and increases the breakdown voltage of the semiconductor device 1.

Here, a comparative example may be considered in which the n-type impurity concentration is equal in all of the regions of the first semiconductor layer 11 (the drift layer). In such a case, even when the n-type impurity concentration of the first semiconductor layer 11 is reduced, the third region 11C in which the third distance d3 between the field plate electrodes 40 is large is not completely depleted, and the breakdown voltage is undesirably determined by the product of the first distance d1 and the n-type impurity concentration of the first region 11A and/or the product of the second distance d2 and the n-type impurity concentration of the second region 11B.

According to the embodiment, the n-type impurity concentrations of the first region 11A and the second region 11B, which are regions having shorter distances between the adjacent field plate electrodes 40 than the third region 11C, are set to be greater than the n-type impurity concentration of the third region 11C. The n-type impurity concentration of the third region 11C, which has a larger distance between the adjacent field plate electrodes 40 than the first and second regions 11A and 11B, is set to be less than the n-type impurity concentration of the first region 11A and the n-type impurity concentration of the second region 11B. Thus, by changing the n-type impurity concentration in the first semiconductor layer 11 according to the distance between adjacent field plate electrodes 40, the timing at which the first region 11A, the second region 11B, and the third region 11C are completely depleted in the off-state can be uniform. As a result, the on-resistance can be reduced while maintaining the breakdown voltage.

The first semiconductor layer 11 further includes a fourth region 11D positioned between the first electrode 21 and the lower end portion of the field plate electrode 40. The fourth region 11D is positioned between the fourth semiconductor layer 14 and the lower end portion of the field plate electrode 40.

The n-type impurity concentration of the fourth region 11D is greater than the n-type impurity concentration of the third region 11C. In such a case, the on-resistance can be reduced.

Or, the n-type impurity concentration of the fourth region 11D is less than the n-type impurity concentration of the first region 11A and the n-type impurity concentration of the second region 11B. In such a case, the electric field concentration at the lower end portion of the field plate electrode 40 can be relaxed, and the breakdown voltage can be increased.

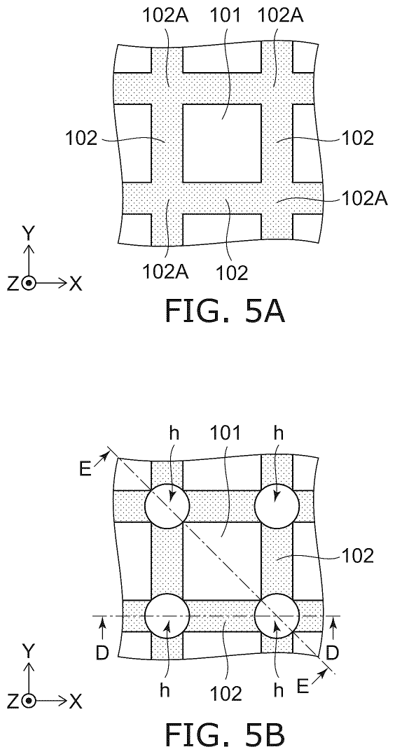

A method for manufacturing the semiconductor device according to the embodiment will now be described with reference to FIGS. 5A to 8B.

The method for manufacturing the semiconductor device according to the embodiment includes a process of forming a first concentration region 101 and a second concentration region 102 in the n-type first semiconductor layer 11. The n-type impurity concentration of the second concentration region 102 is greater than the n-type impurity concentration of the first concentration region 101. The second concentration region 102 is illustrated by dot hatching in FIGS. 5A to 8B. The first region 11A and the second region 11B described above are positioned in the second concentration region 102. The third region 11C described above is positioned in the first concentration region 101.

For example, the second concentration region 102 can be formed by forming the first semiconductor layer 11 of a prescribed thickness of which the entire region is the first concentration region 101, and subsequently implanting an n-type impurity into the first semiconductor layer 11 by ion implantation using a resist mask.

Or, the first semiconductor layer 11 that has the prescribed thickness and includes the first concentration region 101 and the second concentration region 102 can be formed by multiply repeating a process of forming a semiconductor layer of which the entire region is the first concentration region 101, a process of forming the second concentration region 102 by implanting an n-type impurity into the semiconductor layer by ion implantation using a resist mask, a process of forming a new semiconductor layer on the semiconductor layer after the aforementioned ion implantation, and a process of forming the second concentration region 102 by implanting an n-type impurity into the newly formed semiconductor layer by ion implantation using a resist mask.

In the example shown in FIG. 5A, the second concentration region 102 that extends in the first and second directions X and Y is formed. After the second concentration region 102 is formed, a hole h is formed in an intersection part 102A between the second concentration region 102 extending in the first direction X and the second concentration region 102 extending in the second direction Y as shown in FIG. 5B.

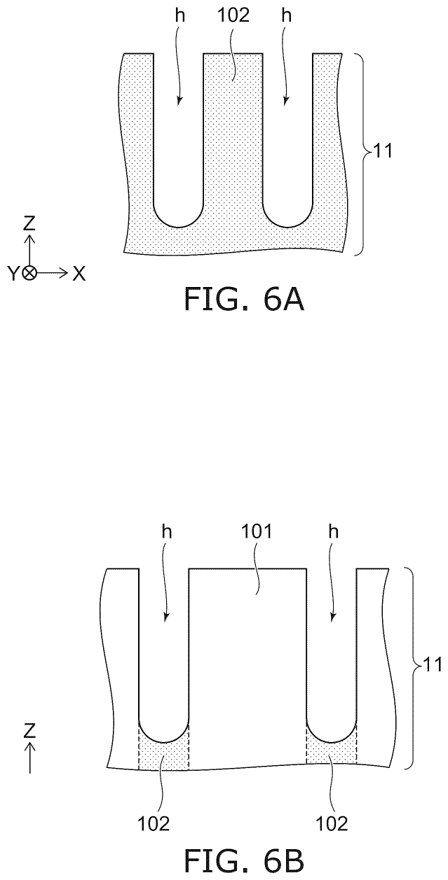

FIG. 6A is a D-D cross-sectional view of FIG. 5B. FIG. 6B is an E-E cross-sectional view of FIG. 5B. The second concentration region 102 is formed in regions in which the distance between the adjacent holes h is relatively short as shown in FIG. 6A; and the first concentration region 101 is formed in regions in which the distance between the adjacent holes h is relatively large as shown in FIG. 6B. When the ion implantation energy is not high, the impurity concentration below the bottom of the hole h may be less than that of the second concentration region 102.

After the holes h are formed, the field plate electrodes 40 are filled into the holes h with the field plate insulating film 52 interposed. The region in which the field plate electrodes 40 are adjacent to each other in the first direction X is the second concentration region 102, which is used to form the first region 11A described above. The region in which the field plate electrodes 40 are adjacent to each other in the second direction Y is the second concentration region 102, which is used to form the second region 11B described above. The region that has a larger distance between the field plate electrodes 40 than the first and second regions 11A and 11B is the first concentration region 101, which is used to form the third region 11C described above.

In the example shown in FIGS. 5A to 6B, the second concentration region 102 is formed in the region below the hole h. In other words, the n-type impurity concentration of the fourth region 11D described above that is below the field plate electrode 40 is greater than the n-type impurity concentration of the third region 11C (the first concentration region 101).

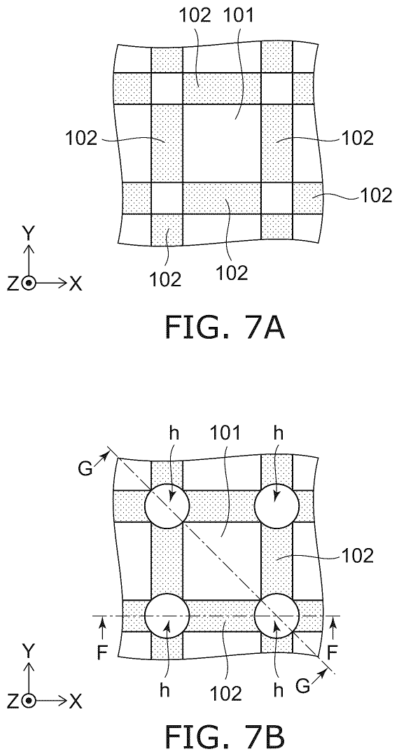

In the example shown in FIG. 7A, the second concentration region 102 is discontinuous in the first and second directions X and Y; and multiple second concentration regions 102 are arranged in the first and second directions X and Y. After the second concentration region 102 is formed, the hole h is formed in the first concentration region 101 between the second concentration regions 102 adjacent to each other in the first direction X, and in the first concentration region 101 between the second concentration regions 102 adjacent to each other in the second direction Y as shown in FIG. 7B.

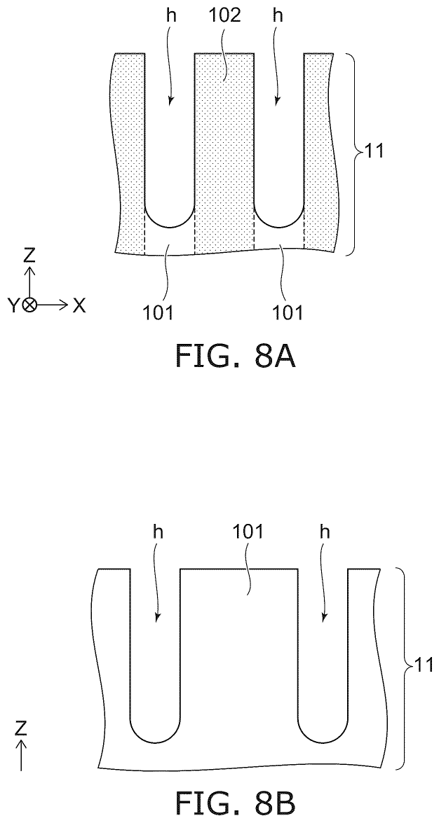

FIG. 8A is an F-F cross-sectional view of FIG. 7B. FIG. 8B is a G-G cross-sectional view of FIG. 7B. The second concentration region 102 is formed in regions in which the distance between the adjacent holes h is relatively short as shown in FIG. 8A; and the first concentration region 101 is formed in regions in which the distance between the adjacent holes h is relatively large as shown in FIG. 8B.

In the example shown in FIGS. 7A to 8B, the first concentration region 101 is formed in the region below the hole h. In other words, the n-type impurity concentration of the fourth region 11D described above that is below the field plate electrode 40 is less than the n-type impurity concentration of the second concentration region 102.

According to the method described above, the second concentration region 102 may be formed by ion implantation after forming the hole h in the first semiconductor layer 11 of a prescribed thickness of which the entire region is the first concentration region 101.

After the field plate electrode 40 is formed, a process of forming a gate trench in the first semiconductor layer 11, a process of filling the gate electrode 30 into the gate trench with the gate insulating film 51 interposed, a process of forming the second semiconductor layer 12 in the first semiconductor layer 11 by ion implantation, a process of forming the third semiconductor layer 13 in the second semiconductor layer 12 by ion implantation, a process of forming the insulating layer 53, a process of forming the second electrode 22, etc., are performed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first electrode;
a second electrode;
a semiconductor part located between the first electrode and the second electrode;
a plurality of field plate electrodes arranged in a first direction and a second direction inside the semiconductor part, the second direction being orthogonal to the first direction; and
a gate electrode positioned between the plurality of field plate electrodes, the gate electrode extending in the first and second directions,
the semiconductor part including
a first semiconductor layer located on the first electrode, the first semiconductor layer being of a first conductivity type,
a second semiconductor layer located on the first semiconductor layer, the second semiconductor layer being of a second conductivity type, and
a third semiconductor layer located on the second semiconductor layer, the third semiconductor layer contacting the second electrode, the third semiconductor layer being of the first conductivity type and having a higher first-conductivity-type impurity concentration than the first semiconductor layer,
the first semiconductor layer including
a first region positioned between field plate electrodes among the plurality of field plate electrodes adjacent to each other in the first direction,
a second region positioned between field plate electrodes among the plurality of field plate electrodes adjacent to each other in the second direction, and
a third region positioned between field plate electrodes among the plurality of field plate electrodes adjacent to each other with an intersection part interposed, the intersection part being between the gate electrode extending in the first direction and the gate electrode extending in the second direction,
a first-conductivity-type impurity concentration of the first region and a first-conductivity-type impurity concentration of the second region being greater than a first-conductivity-type impurity concentration of the third region.

2. The device according to claim 1, wherein
the first semiconductor layer includes a fourth region positioned between the first electrode and at least one of the field plate electrodes, and
a first-conductivity-type impurity concentration of the fourth region is greater than the first-conductivity-type impurity concentration of the third region.

3. The device according to claim 1, wherein
the first semiconductor layer includes a fourth region positioned between the first electrode and at least one of the field plate electrodes, and
a first-conductivity-type impurity concentration of the fourth region is less than the first-conductivity-type impurity concentration of the first region and the first-conductivity-type impurity concentration of the second region.

4. The device according to claim 1, wherein
the semiconductor part further includes a fourth semiconductor layer located between the first electrode and the first semiconductor layer, the fourth semiconductor layer contacting the first electrode, the fourth semiconductor layer being of the first conductivity type.

5. The device according to claim 4, wherein
the plurality of field plate electrodes does not reach the fourth semiconductor layer.

6. The device according to claim 1, wherein
the semiconductor part further includes a fourth semiconductor layer located between the first electrode and the first semiconductor layer, the fourth semiconductor layer contacting the first electrode, the fourth semiconductor layer being of the second conductivity type.

7. The device according to claim 6, wherein
the plurality of field plate electrodes does not reach the fourth semiconductor layer.

8. The device according to claim 1, wherein
a third distance is greater than a first distance,
the third distance is a shortest distance between the field plate electrodes adjacent to each other with the intersection part of the gate electrode interposed, and
the first distance is a shortest distance between the field plate electrodes adjacent to each other in the first direction.

9. The device according to claim 8, wherein
the third distance is greater than a second distance,
the second distance is a shortest distance between the field plate electrodes adjacent to each other in the second direction.

10. The device according to claim 1, wherein
a third distance is greater than a second distance,
the third distance is a shortest distance between the field plate electrodes adjacent to each other with the intersection part of the gate electrode interposed, and
the second distance is a shortest distance between the field plate electrodes adjacent to each other in the second direction.

11. The device according to claim 1, wherein
the first-conductivity-type impurity concentration of the first region and the first-conductivity-type impurity concentration of the second region are not less than 1.2 times and not more than 1.4 times the first-conductivity-type impurity concentration of the third region.

12. The device according to claim 1, wherein
the plurality of field plate electrodes is electrically connected with the second electrode.

13. The device according to claim 1, wherein
each of the plurality of field plate electrodes is columnar, and
the plurality of field plate electrodes has a square lattice arrangement in the first and second directions.

14. The device according to claim 1, wherein
a shortest distance in a third direction between the first electrode and lower end portions of the plurality of field plate electrodes is less than a shortest distance in the third direction between the first electrode and a lower end portion of the gate electrode, and
the third direction is orthogonal to the first and second directions.

15. A method for manufacturing a semiconductor device, the method comprising:
forming a first concentration region and a second concentration region in a first semiconductor layer of a first conductivity type, the second concentration region extending in a first direction and a second direction, the second direction being orthogonal to the first direction, the second concentration region having a higher first-conductivity-type impurity concentration than the first concentration region; and
filling a field plate electrode into a hole with an insulating film interposed, the hole being positioned at an intersection part between the second concentration region extending in the first direction and the second concentration region extending in the second direction.

16. The method according to claim 15, wherein
the hole is formed in the intersection part after the second concentration region is formed.

17. The method according to claim 15, wherein
the second concentration region is formed by implanting a first-conductivity-type impurity into the first semiconductor layer by ion implantation using a resist mask.

18. A method for manufacturing a semiconductor device, the method comprising:
forming a first concentration region and a plurality of second concentration regions in a first semiconductor layer of a first conductivity type, the plurality of second concentration regions being arranged in a first direction and a second direction, the second direction being orthogonal to the first direction, the plurality of second concentration regions having a higher first-conductivity-type impurity concentration than the first concentration region; and
filling field plate electrodes into holes with insulating films interposed, the holes including
a hole positioned in the first concentration region between the second concentration regions adjacent to each other in the first direction, and
a hole positioned in the first concentration region between the second concentration regions adjacent to each other in the second direction.

19. The method according to claim 18, wherein
the hole is formed in the first concentration region after the second concentration region is formed.

20. The method according to claim 18, wherein
the second concentration region is formed by implanting a first-conductivity-type impurity into the first semiconductor layer by ion implantation using a resist mask.
